(19) United States
(12) Patent Application Publication
(10) Pub. No.: US 2012/0228721 A1
(43) Pub. Date: Sep. 13, 2012

(54) SEMICONDUCTOR DEVICE AND REFERENCE VOLTAGE GENERATION CIRCUIT

(76) Inventor: Hideo YOSHINO, Chiba-shi (JP)

(21) Appl. No.: 13/414,790

(22) Filed: Mar. 8, 2012

(30) Foreign Application Priority Data
Mar. 13, 2011 (JP) 2011-054898

(51) Int. Cl. H01L 27/088; H01L 29/78

(52) U.S. Cl. 257/392; 257/288; 257/E29.255; 257/E27.061

(57) ABSTRACT

In a gate electrode (40) provided on a gate insulating film (30), a depletion layer (42) is formed at a junction surface between a P-type semiconductor layer (41) and a gate insulating film (30). Since a region of the depletion layer (42) inside the gate electrode (40) changes due to temperature change, inducing a change in an effect of a gate voltage to channel formation, a threshold voltage changes to a larger extent than in a case of a typical MOS transistor. This is used to control the MOS transistor to have a desired temperature characteristic. A temperature compensation circuit may be eliminated and the circuit scale may be reduced.

### BACKGROUND OF THE INVENTION

1. Field of the Invention

The present invention relates to a semiconductor device having a MOS transistor with a depletion layer in a gate electrode.

2. Description of the Related Art

A transistor constituting a semiconductor device generally has a temperature characteristic and changes in characteristics with temperature. Accordingly, a variety of devices using the transistor also have temperature characteristics. A semiconductor temperature sensor is a semiconductor device that positively utilizes the significant change in temperature characteristics. On the other hand, there is a semiconductor device that is required to show as less change in characteristics as possible against the temperature change. In order to realize such a semiconductor device, both the transistor and the circuit need to be specially designed.

For example, in a case of a reference voltage generation circuit, when the temperature changes, a reference voltage, which is an output voltage of the reference voltage generation circuit, also changes. In a technology disclosed in Japanese Patent Application Laid-open No. Hei 11-134051, a temperature compensation circuit is provided for temperature compensation of the reference voltage, which increases the circuit scale.

### SUMMARY OF THE INVENTION

The present invention has been made in view of the above-mentioned problem to provide a semiconductor device capable of reducing a scale of a compensation circuit or eliminating the compensation circuit by imparting a desired temperature characteristic to a MOS transistor.

In order to solve the above-mentioned problem, according to the present invention, there is provided a semiconductor device having a MOS transistor, the MOS transistor comprises: a source region and a drain region provided in a semiconductor substrate of a first conductivity type; a gate insulating film provided above a region between the source region and the drain region; and a gate electrode provided on the gate insulating film, in which the gate electrode includes, in a vertical direction of the semiconductor substrate, a semiconductor layer of a second conductivity type, and a depletion layer formed at a junction surface between the semiconductor layer of the second conductivity type and a layer under the semiconductor layer of the second conductivity type.

In the semiconductor device of the present invention, the thickness of the depletion layer inside the gate electrode changes causing a change in the effect of the gate voltage to channel formation in the temperature change, which increases the number of factors for controlling a threshold voltage compared to the case of a standard MOS transistor. This may be used to impart a desired temperature characteristic to the MOS transistor, which allows use of a small temperature compensation circuit, permitting a reduction in the circuit scale.

### BRIEF DESCRIPTION OF THE DRAWINGS

In the accompanying drawings:

FIG. 1 is a cross-sectional view illustrating a first embodiment of the present invention;

FIG. 2 is a cross-sectional view illustrating a second embodiment of the present invention; and

FIG. 3 is a circuit diagram illustrating a reference voltage generation circuit according to a third embodiment of the present invention.

### DETAILED DESCRIPTION OF THE PREFERRED EMBODIMENTS

Hereinafter, embodiments of the present invention are described with reference to the accompanying drawings.

### First Embodiment

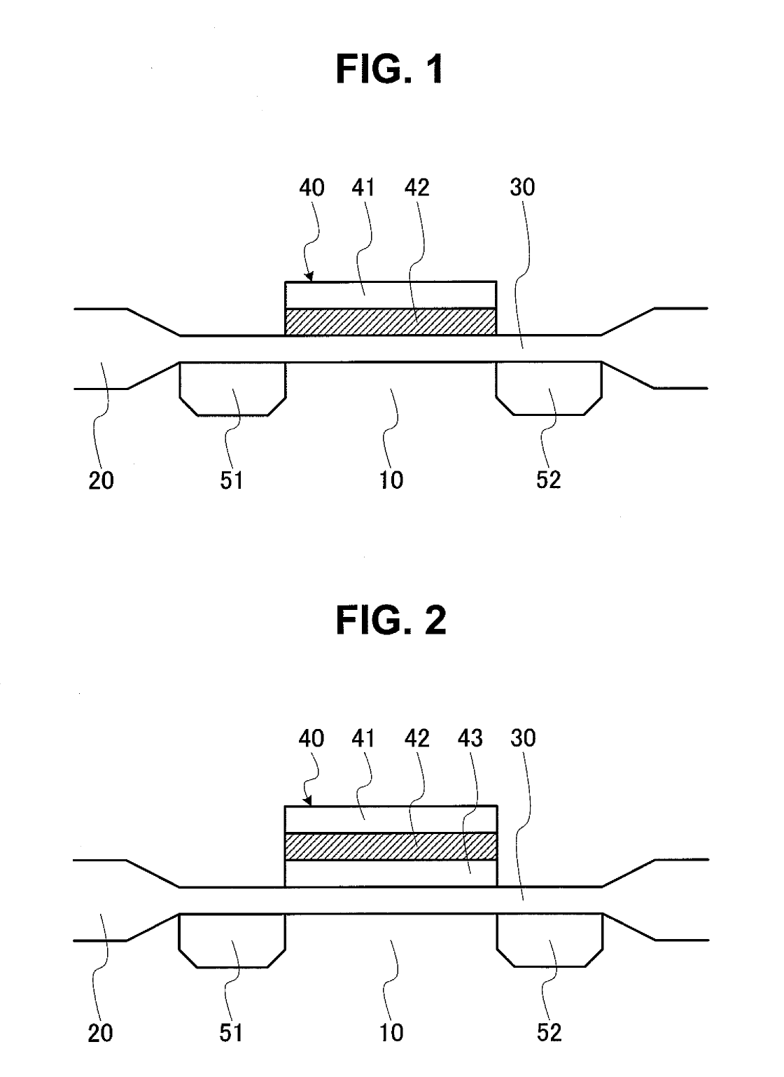

First, a structure of a MOS transistor is described. FIG. 1 is a cross-sectional view illustrating a MOS transistor according to a first embodiment of the present invention.

The MOS transistor includes a semiconductor substrate 10 of a first conductivity type, a field insulating film 20, a gate insulating film 30, a gate electrode 40, a source region 51, and a drain region 52. The gate electrode 40 includes, in a vertical direction of the semiconductor substrate 10, a semiconductor layer 41 of a second conductivity type and a depletion layer 42, which is formed by depleting the semiconductor layer of the second conductivity type. The gate insulating film 30 is provided above a region between the source region 51 and the drain region 52. The gate electrode 40 is provided on the gate insulating film 30. The depletion layer 42 is formed at a junction surface between the semiconductor layer 41 of the second conductivity type and a layer (gate insulating film 30) under the semiconductor layer 41 of the second conductivity type. When the first conductivity type is N-type, the second conductivity type is P-type.

At this point, in order to deplete the lower side of the gate electrode, the conductivity type of the gate electrode and the conductivity type of the semiconductor substrate under the gate electrode need to be different.

The region of the semiconductor substrate of the first conductivity type in which the MOS transistor is formed is electrically isolated from the surrounding region in the vicinity of the surface of the semiconductor substrate with the field insulating film 20 having a thickness of about 100 to 500 nm by local oxidation of silicon (LOCOS) or by shallow trench isolation (STI) in which an oxide film is embedded to a depth of about 50 to 300 nm (not shown). Then, the gate insulating film 30 having a thickness of about 5 to 100 nm is provided. Then, the gate electrode 40 having a thickness of about 200 to 300 nm is provided on the gate insulating film 30. The gate electrode 40 is ion-implanted with impurities to form the semiconductor layer 41 of the second conductivity type. At this point, the concentration of the impurities for implantation needs to be determined to induce a depletion in the lower part of the gate electrode due to the potential difference from the semiconductor substrate. Then, the source region 51 and the drain region 52 are formed by ion implantation of impurities.

Next, the operation of the MOS transistor of the embodiment is described.

In a typical MOS transistor, the thickness of the gate insulating film does not change and the gate electrode does not show depletion against the temperature change, and hence the capacitance of the gate insulating film hardly changes. In the embodiment, however, the thickness of the depletion layer 42 in the lower part of the gate electrode 40 of the MOS transistor changes against the temperature change. Since the depletion layer has a capacitance, a change in the thickness of the depletion layer has a similar effect to a change in the thickness of the gate insulating film inducing a change in the capacitance of the gate insulating film.

Since the threshold voltage has generally an inherent temperature characteristic in a MOS transistor, the threshold voltage changes due to the temperature change. On the other hand, in the MOS transistor of the embodiment, the change in the capacitance of the gate insulating film due to the change in the thickness of the depletion layer leads to a change in the effect of the gate voltage to the channel formation, causing the threshold voltage to change further or causing the changes to cancel each other so that the threshold voltage hardly changes against the temperature change. In this manner, desired temperature characteristics may be imparted to the MOS transistor.

As described above, formation of a MOS transistor having a desired temperature characteristic enables a simple construction of the temperature compensation circuit or a reduction of the circuit scale. Depending on the temperature characteristic of the MOS transistor, the temperature compensation circuit may be eliminated.

### Modified Example 1

In FIG. 1, the semiconductor layer 41 whose conductivity type is P-type is used, but an N-type semiconductor layer may be used instead. In this case, the conductivity type of the semiconductor substrate is P-type.

### Second Embodiment

FIG. 2 illustrates a second embodiment of the present invention. As illustrated in FIG. 2, the gate electrode 40 further includes an N-type semiconductor layer 43 in the vertical direction of the P-type semiconductor substrate 10. At this point, the depletion layer 42 develops at a junction surface between the P-type semiconductor layer 41 and a layer (N-type semiconductor layer 43) below the P-type semiconductor layer 41.

In a typical MOS transistor, even when the temperature changes, a part of the gate voltage applied to the channel does not change. However, in a MOS transistor according to the second embodiment illustrated in FIG. 2, since a diode formed by the P-type semiconductor layer 41 and the N-type semiconductor layer 43 is reverse-biased and the depletion layer is present, the thickness of the depletion layer 42 changes, and the capacitive coupling between the P-type semiconductor layer 41 and the N-type semiconductor layer 43 changes as well due to the temperature change. Accordingly, the voltage applied to the semiconductor substrate 10 for channel formation of the gate voltage (voltage of the P-type semiconductor layer 41) also changes.

Since the threshold voltage has an inherent temperature characteristic in a MOS transistor, the threshold voltage changes in the temperature change. In the MOS transistor of FIG. 2, the change in the voltage applied to the channel of the gate voltage leads to the change in the effect of the gate voltage on the channel formation, permitting a further change of the threshold voltage due to the temperature change.

### Modified Example 2

In FIG. 2, the N-type semiconductor layer 43 is provided below the P-type semiconductor layer 41. Although not shown, when the semiconductor substrate is N-type, it is preferred to provide the N-type semiconductor layer 43 above the P-type semiconductor layer 41.

### Third Embodiment

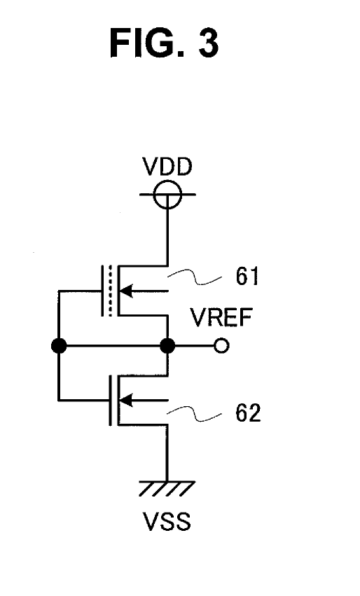

FIG. 3 is a circuit diagram illustrating a third embodiment of the present invention, and illustrates a reference voltage generation circuit. The MOS transistor illustrated in FIG. 1 or 2 may be applied to the reference voltage generation circuit illustrated in FIG. 3. The reference voltage generation circuit includes a depletion type MOS transistor 61 and an enhancement type MOS transistor 62. The MOS transistor 61 includes a gate and a source connected to each other and to an output terminal, and a drain connected to a power supply terminal. The MOS transistor 62 is provided and diode-connected between the source of the MOS transistor 61 and a ground terminal. The MOS transistor 61 serves as a current source for supplying a constant current, which generates a reference voltage VREF at a drain of the diode-connected MOS transistor 62. In this circuit, the MOS transistors 61 and 62 are controlled to have desired temperature characteristics, and hence it is possible to impart a desired temperature coefficient to the reference voltage VREF.

What is claimed is:

1. A semiconductor device, comprising:
a semiconductor substrate of a first conductivity type;
a source region and a drain region provided on a surface of the semiconductor substrate; and
a gate electrode provided on a gate insulating film, and above a region between the source region and the drain region,
wherein the gate electrode comprises a semiconductor layer of a second conductivity type, and a depletion layer formed under the semiconductor layer of the second conductivity type.

2. A semiconductor device according to claim 1,
further comprising a semiconductor layer of a first conductivity type under the semiconductor layer of the second conductivity type, and
wherein the depletion layer is formed at a junction surface between the semiconductor layer of the first conductivity type and the semiconductor layer of the second conductivity type.

3. A semiconductor device according to claim 1, wherein the depletion layer is formed at a junction surface between the semiconductor layer of the second conductivity type and the gate insulating film.

4. A reference voltage generation circuit, comprising:
a depletion type MOS transistor including a gate and a source connected to each other, and a drain connected to a power supply terminal; and
an enhancement type MOS transistor, which is diode-connected between the source and a ground terminal,
wherein each of the depletion type MOS transistor and the enhancement type MOS transistor comprises the semiconductor device according to claim 1.

5. A reference voltage generation circuit, comprising:
a depletion type MOS transistor including a gate and a source connected to each other, and a drain connected to a power supply terminal; and
an enhancement type MOS transistor, which is diode-connected between the source and a ground terminal,
wherein each of the depletion type MOS transistor and the enhancement type MOS transistor comprises the semiconductor device according to claim 2.

6. A reference voltage generation circuit, comprising:
a depletion type MOS transistor including a gate and a source connected to each other, and a drain connected to a power supply terminal; and
an enhancement type MOS transistor, which is diode-connected between the source and a ground terminal,
wherein each of the depletion type MOS transistor and the enhancement type MOS transistor comprises the semiconductor device according to claim 3.
